(19) United States
(12) Patent Application Publication
(10) Pub. No.: US 2026/0243854 A1
(43) Pub. Date: Aug. 20, 2026

(54) QUANTUM AND MAGNONIC-BASED MAGNETOMETER DRIVEN WITH AN ULTRALOW PHASE AND AMPLITUDE NOISE OSCILLATOR

(71) Applicant: RTX BBN Technologies, Inc., Cambridge, MA (US)

(72) Inventors: James Andrew Dervay, Northborough, MA (US); Erik Eisenach, Cambridge, MA (US); Jason D. Adams, Medway, MA (US); Matthew A. Morton, Lynnfield, MA (US); Graham E. Rowlands, Arlington, MA (US); Moe D. Soltani, Belmont, MA (US)

(21) Appl. No.: 19/545,765

(22) Filed: Feb. 20, 2026

Related U.S. Application Data
(60) Provisional application No. 63/760,764, filed on Feb. 20, 2025.

(51) Int. Cl. G01R 33/12; G01R 33/02

(52) U.S. Cl. CPC G01R 33/1284; G01R 33/0206

(57) ABSTRACT

A magnetometer may include an oscillator to generate a carrier signal, one or more sensor heads, each including a pair of ferrimagnetic resonators with resonant frequencies matched to the carrier signal, one or more magnets configured to bias the pair of ferrimagnetic resonators with opposing magnetic bias fields, where an external magnetic field in a measurement direction aligned with the opposing magnetic bias fields modifies the resonant frequencies of the pair of ferrimagnetic resonators in opposite directions, and a pair of phase detectors configured to measure phase shifts of the carrier signal by the pair of ferrimagnetic resonators. The magnetometer may also include differential detection circuitry to generate a detection signal indicative of a strength of the external magnetic field along the measurement direction associated with each of the one or more sensor heads based on a differential measurement of the phase shifts.

### CROSS-REFERENCE TO RELATED APPLICATION

The present application claims the benefit under 35 U.S.C. § 119 (e) of U.S. Provisional Application Ser. No. 63/760,764, filed Feb. 20, 2025, naming James Andrew Dervay, Erik Eisenach, Jason D. Adams, Matthew A. Morton, Graham E. Rowlands, and Moe D. Soltani as inventors, which is incorporated herein by reference in the entirety.

### TECHNICAL FIELD

The present disclosure relates generally to magnetometers and, more particularly, to a quantum magnonic-based magnetometer.

### BACKGROUND

Several quantum magnetometer sensors exist today, spanning a wide range of technological maturity. However, existing sensors fail to provide desired levels of sensitivity and/or robustness

For example, the superconducting quantum interference device (SQUID) have demonstrated relatively magnetic sensitivity, they rely on cryogenic cooling and bulky infrastructure, which limits their suitability for many applications. As another example, the optically pumped atomic magnetometer (OPM) may operate at room temperature, but their centimeter scale sensing volume makes them highly susceptible to stray magnetic field gradients, and they suffer from substantial dead zones that are difficult to mitigate. As a result, deploying OPMs in harsh environments remains a significant challenge. As another example, solid-state magnetometers, such as those utilizing nitrogen-vacancy color centers in diamond, may provide intrinsic dead-zone-free vector sensing at room temperature, but require extremely high laser power and complex electronic and optomechanical setups to achieve high sensitivity.

Magnetometers based on spin-wave interferometry in ferrimagnetic materials (e.g. YIG) have shown significant promise as quantum sensors. These devices offer seamless electronic integration without the need for complex and high-power optical components, while demonstrating high dynamic range and high sensitivity. However, current techniques fail to provide high sensitivity over a wide range of frequencies, particularly lower frequencies (e.g., <1 kHz)

There is therefore a need to develop systems and methods to address the above deficiencies.

### SUMMARY

In embodiments, the techniques described herein relate to a magnetometer including an oscillator configured to generate a carrier signal; one or more sensor heads, each including a pair of ferrimagnetic resonators with resonant frequencies matched to the carrier signal; one or more magnets configured to bias the pair of ferrimagnetic resonators with opposing magnetic bias fields, where an external magnetic field in a measurement direction aligned with the opposing magnetic bias fields modifies the resonant frequencies of the pair of ferrimagnetic resonators in opposite directions; and a pair of phase detectors configured to measure phase shifts of the carrier signal by the pair of ferrimagnetic resonators, where the phase shifts are correlated to the resonant frequencies; and differential detection circuitry configured to generate a detection signal indicative of a strength of the external magnetic field along the measurement direction associated with each of the one or more sensor heads based on a differential measurement of the phase shifts in each of the one or more sensor heads.

In embodiments, the techniques described herein relate to a magnetometer, where the one or more magnets include a biased yoke magnet, where the pair of ferrimagnetic resonators are placed in opposite regions of the biased yoke magnet.

In embodiments, the techniques described herein relate to a magnetometer, where the pair of phase detectors include interferometric carrier-suppression bridges to control noise in the detection signal.

In embodiments, the techniques described herein relate to a magnetometer, where the pair of ferrimagnetic resonators include yttrium iron garnet (YIG) resonators.

In embodiments, the techniques described herein relate to a magnetometer, further including tuning circuitry to match the resonant frequencies of the pair of ferrimagnetic resonators and a frequency of the carrier signal.

In embodiments, the techniques described herein relate to a magnetometer, further including a thermal controller to control a temperature of at least one of the one or more sensor heads.

In embodiments, the techniques described herein relate to a magnetometer, where the one or more sensor heads include three sensor heads arranged in orthogonal directions, where the detection signals from the three sensor heads provide a three-dimensional measurement of the external magnetic field.

In embodiments, the techniques described herein relate to a magnetometer, where the one or more sensor heads include an array of sensor heads.

In embodiments, the techniques described herein relate to a magnetometer sensor head including a pair of ferrimagnetic resonators; one or more magnets configured to bias the pair of ferrimagnetic resonators with opposing magnetic bias fields, where an external magnetic field in a measurement direction aligned with the opposing magnetic bias fields modifies resonant frequencies of the pair of ferrimagnetic resonators in opposite directions; and a pair of phase detectors configured to measure phase shifts of a carrier signal by the pair of ferrimagnetic resonators, where a frequency of the carrier signal matches the resonant frequencies of the pair of ferrimagnetic resonators, where the phase shifts are correlated to the resonant frequencies, where a differential measurement of the phase shifts provides a measurement of the external magnetic field along the measurement direction.

In embodiments, the techniques described herein relate to a magnetometer sensor head, where the one or more magnets include a biased yoke magnet, where the pair of ferrimagnetic resonators are placed in opposite regions of the biased yoke magnet.

In embodiments, the techniques described herein relate to a magnetometer sensor head, where the pair of phase detectors include interferometric carrier-suppression bridges.

In embodiments, the techniques described herein relate to a magnetometer sensor head, where the pair of ferrimagnetic resonators include yttrium iron garnet (YIG) resonators.

In embodiments, the techniques described herein relate to a magnetometer sensor head, further including tuning circuitry to match the resonant frequencies of the pair of ferrimagnetic resonators and a frequency of the carrier signal.

In embodiments, the techniques described herein relate to a magnetometer sensor head, further including a thermal controller to control a temperature of the pair of ferrimagnetic resonators.

In embodiments, the techniques described herein relate to a magnetometry method including coupling a carrier signal to one or more sensor heads, each including a pair of ferrimagnetic resonators with resonant frequencies matched to the carrier signal; and one or more magnets configured to bias the pair of ferrimagnetic resonators with opposing magnetic bias fields, where an external magnetic field in a measurement direction aligned with the opposing magnetic bias fields modifies resonant frequencies of the pair of ferrimagnetic resonators in opposite directions; measuring phase shifts of the carrier signal by the pair of ferrimagnetic resonators in each of the one or more sensor heads, where the phase shifts are correlated to the resonant frequencies; and generating a detection signal indicative of a strength of the external magnetic field along the measurement direction associated with each of the one or more sensor heads based on a differential measurement of the phase shifts in each of the one or more sensor heads.

In embodiments, the techniques described herein relate to a magnetometry method, further including tuning the resonant frequencies of the pair of ferrimagnetic resonators to match a frequency of the carrier signal.

In embodiments, the techniques described herein relate to a magnetometry method, further including controlling a temperature of at least one of the one or more sensor heads.

In embodiments, the techniques described herein relate to a magnetometry method, where the one or more magnets include a biased yoke magnet, where the pair of ferrimagnetic resonators are placed in opposite regions of the biased yoke magnet.

In embodiments, the techniques described herein relate to a magnetometry method, where measuring the phase shifts of the carrier signal by the pair of ferrimagnetic resonators includes measuring the phase shifts via interferometric carrier-suppression bridges to control noise in the detection signal.

In embodiments, the techniques described herein relate to a magnetometry method, where the one or more sensor heads include three sensor heads arranged in orthogonal directions, where generating the detection signal indicative of the strength of the external magnetic field along the measurement direction based on the differential measurement of the phase shifts includes generating detection signals indicative of the strength of the external magnetic field along the orthogonal directions.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1A illustrates a block diagram view of a quantum magnonic interferometer, in accordance with one or more embodiments of the present disclosure.

FIG. 1B illustrates a schematic of a quantum magnonic interferometer including three sensor heads, in accordance with one or more embodiments of the present disclosure.

FIG. 2 illustrates a schematic view of spins in a spherical ferrimagnetic resonator, in accordance with one or more embodiments of the present disclosure.

FIG. 3 illustrates common-mode noise rejection using a pair of ferrimagnetic resonators in the presence of opposing applied magnetic bias fields.

FIG. 4 illustrates a plot of magnitude and phase of a resonance of a ferrimagnetic resonator, in accordance with one or more embodiments of the present disclosure.

FIG. 5A illustrates a diagram of phase detectors and differential detection circuitry in a sensor head, in accordance with one or more embodiments of the present disclosure.

FIG. 5B illustrates a diagram of an interferometric carrier suppression bridge in a phase detector, in accordance with one or more embodiments of the present disclosure.

FIG. 6 illustrates a plot of sensitivity of the quantum magnonic interferometer limited by different noise sources, in accordance with one or more embodiments of the present disclosure.

FIG. 7A illustrates a side schematic view of a sensor head, in accordance with one or more embodiments of the present disclosure.

FIG. 7B illustrates a top schematic view of a circuit board for interfacing with the ferrimagnetic resonators, in accordance with one or more embodiments of the present disclosure.

FIG. 7C is a perspective view of the sensor head associated with FIGS. 7A and 7B, except that the circuit board is shown as two components instead of a single component as in FIG. 7B, in accordance with one or more embodiments of the present disclosure.

FIG. 8 is a block diagram of a magnetometry method, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods providing a quantum magnonic magnetometer providing broadband measurements of magnetic fields in a small and robust package.

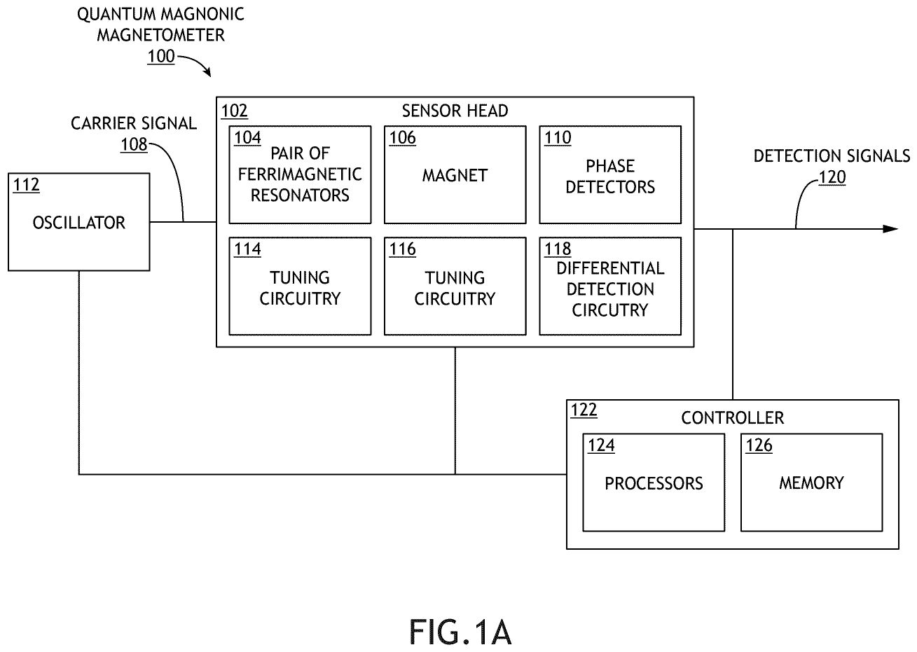

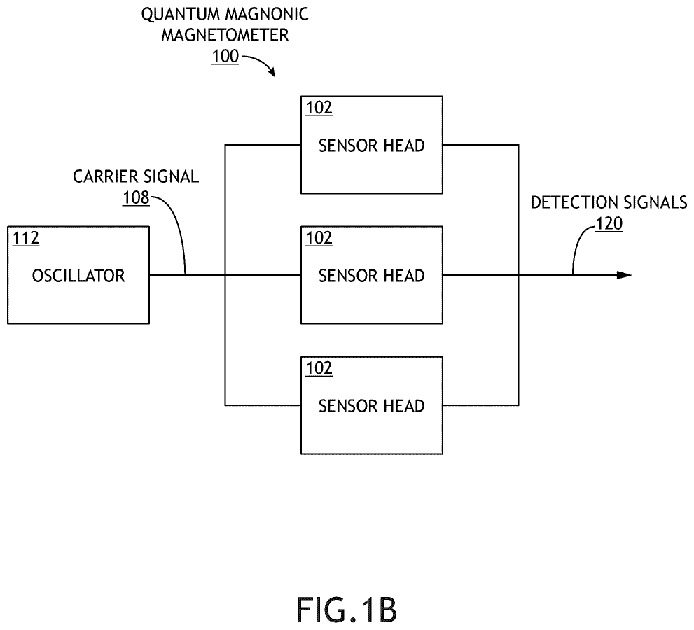

FIG. 1A illustrates a block diagram view of a quantum magnonic interferometer 100, in accordance with one or more embodiments of the present disclosure.

In embodiments, the quantum magnonic interferometer 100 includes one or more sensor heads 102, each with a pair of ferrimagnetic resonators 104 and one or more magnets 106 configured to provide opposite magnetic bias fields across the pair of ferrimagnetic resonators 104.

It is contemplated herein that ferrimagnetic resonators 104 may have bulk quantum spin waves (e.g., magnons) with frequencies that tune strongly with applied magnetic fields. In this configuration, a component of an external magnetic field (e.g., a signal of interest to be measured) aligned along a direction associated with the opposing bias fields (e.g., a measurement direction) may shift the resonant frequencies of the ferrimagnetic resonators with opposing signs. For example, the resonant frequency of one ferrimagnetic resonator 104 in a pair may increase and the resonant frequency of the other ferrimagnetic resonator 104 in the pair may decrease.

The quantum magnonic interferometer 100 may include any type of ferrimagnetic resonators 104 having resonances sensitive to external electric fields. In some embodiments, the ferrimagnetic resonators 104 are formed as spherical resonators. The ferrimagnetic resonators 104 may further be formed from any ferrimagnetic material such as, but not limited to, yttrium iron garnet (YIG) or magnetite. For example, a spherical YIG resonator may have an ultra-high spin density (e.g., around 4×10²¹ cm⁻³ in some cases), long spin times, and a high quality factor (e.g., Q greater than 3000 in some cases), which may provide sensitive magnetic detection. However, this is merely an illustration and not limiting on the scope of the present disclosure.

The resonance frequency of a ferrimagnetic resonator 104 may depend on various factors including, but not limited to, the composition, temperature, the resonator size, and a strength of an applied magnetic field (e.g., an applied magnetic bias field and/or an external magnetic field to be measured). Continuing the example above, a spherical YIG ferrimagnetic resonator 104 with approximately 1 mm diameter in the presence of an approximately 0.2 Tesla bias field may have a resonance frequency of approximately 5 GHz.

The impact of an external magnetic field on resonances of the pair of ferrimagnetic resonators 104 may be determined using any suitable technique. In some embodiments, as shown in FIG. 1A, the impact of an external magnetic field on resonances of the pair of ferrimagnetic resonators 104 is determined by probing the ferrimagnetic resonators 104 with a carrier signal 108 tuned to a nominal resonance frequency of the ferrimagnetic resonators 104 (e.g., a resonance frequency in the absence of an external magnetic field). In this configuration, changes in the resonance frequencies due to the presence of an external magnetic field may impart phase shifts to the carrier signals 108, again with opposing signs.

Accordingly, sensor heads 102 may include phase detectors 110 to measure the phases of the carrier signals 108 after interaction with the ferrimagnetic resonators 104 and may further include differential detection circuitry 118 to generate detection signals 120 based on differential measurements of the phases of the carrier signals 108.

As shown in FIG. 1A, the quantum magnonic interferometer 100 may include an oscillator 112 to generate the carrier signal 108. However, this is not a requirement and the oscillator 112 may be external to the quantum magnonic interferometer 100.

In some embodiments, a sensor head 102 includes tuning circuitry 114 configured to tune the nominal resonance frequencies of either or both of the ferrimagnetic resonators 104. The tuning circuitry 114 may include any component or combination of components suitable for modifying the resonance frequency of a ferrimagnetic resonator 104. For example, the tuning circuitry 114 may include one or more individually-controllable electromagnets or coils suitable for inducing or modifying a magnetic field across a ferrimagnetic resonator 104, which may in turn tune the associated resonance frequency. Further, the tuning circuitry 114 in different sensor heads 102 may adjust the nominal reference frequencies of all ferrimagnetic resonators 104 to match each other and a frequency of the carrier signal 108.

In some embodiments, a sensor head 102 may include a temperature controller 116 to maintain a temperature of any of the constituent components. In this way, the temperature controller 116 may mitigate temperature-based noise in a measurement. The temperature controller 116 may include any component or combination of components suitable for temperature control such as, but not limited to, one or more heaters. In this way,

As an illustration, typical spherical YIG ferrimagnetic resonators 104 may have a temperature frequency slope of 500 KHz/C and hence a temperature phase slope of

$$\frac{d θ}{d T} = 500 [ \frac{kHz}{degC} ] \times 1.4 E - 6 [ \frac{rad}{Hz} ] = 0.7 [ \frac{rad}{degC} ] .$$

A modest electro-thermal control system can maintain the temperature to within +/−0.005 C, resulting in a phase error of

$$0.7 [ \frac{rad}{degC} ] \times 0.005 [ degC ] = 3.5 mRad .$$

Further, the typical spherical YIG ferrimagnetic resonators 104 may have a thermal time constant of approximately τ=0.4 s which may naturally suppress thermal noise greater than 2.5 Hz. Slower thermal drifts may be compensated through temperature control or other control loops.

A sensor head 102 may include any number or type of magnets 106 to provide opposite magnetic bias fields across the pair of ferrimagnetic resonators 104. In some embodiments, the pair of ferrimagnetic resonators 104 are located in opposite regions of a biased yoke magnet 106. In this configuration, magnetic bias noise (e.g., fluctuations in the magnetic bias fields due to vibrations or other factors) may be common for the pair of ferrimagnetic resonators 104 and may likewise be mitigated or removed to provide robust and sensitive performance.

A quantum magnonic magnetometer may include any number of sensor heads oriented in any directions to provide comprehensive magnetic field measurements. For example, three sensor heads aligned along orthogonal directions may provide three-dimensional measurements. FIG. 1B illustrates a schematic of a quantum magnonic interferometer 100 including three sensor heads 102, in accordance with one or more embodiments of the present disclosure. More generally, this system may be scaled into a sensor array.

In embodiments, the quantum magnonic interferometer 100 includes a controller 122. The controller 122 may include one or more processors suitable for executing program instructions stored on a memory device such as, but not limited to, a non-transitory memory device. For instance, the controller 122 may include a digital signal processor (DSP), a field-programmable gate array (FPGA) device, an application-specific integrated circuit (ASIC), a central processing unit (CPU), or a graphical processing unit (GPU).

The controller 122 may be coupled with any components of the quantum magnonic interferometer 100 such as, but not limited to, one or more sensor heads 102, or the oscillator 112.

In some embodiments, the controller 122 may analyze, process, or otherwise operate on data from any component. In some embodiments, the controller 122 may generate control signals to direct the operation of any component through direct commands, feedback control techniques, feed-forward control techniques, or any other suitable control technique. For example, the controller 122 may control the tuning circuitry 114 and/or the oscillator 112 to provide that the resonance frequencies of the various ferrimagnetic resonators 104 match each other and in some cases a frequency of the carrier signal 108 from the oscillator. As another example, the controller 122 may control the operation of the temperature controllers 116 in at least one of the sensor heads 102. As another example, the controller 122 may receive detection signals 120 from any number of sensor heads 102 and perform additional processing. For instance, the controller 122 may generate a three-dimensional (e.g., vector) representation of an external magnetic field from multiple sensor heads 102. In another instance, the controller 122 may perform signal averaging or analysis from multiple sensor heads 102 in an array configuration.

It is contemplated that the quantum magnonic magnetometer disclosed herein may provide robust and sensitive measurements based through both the system design and noise processing techniques. For example, differential measurements of a pair of ferrimagnetic resonators biased with opposing magnetic fields may mitigate common magnetic bias noise. As another example, interrogating all of the resonators with a common carrier signal 108 (e.g., as shown in FIG. 1A) may enable mitigation of noise from this common carrier signal during a measurement and/or using post-processing techniques. Further, interferometric noise suppression techniques may reduce the effective noise contribution of phase detectors.

It is further contemplated herein that the systems and methods disclosed herein may be implemented in a compact, ruggedized platform suitable for demanding applications. In some embodiments, each sensor head may have a form factor equal to or less than 5 L. Further, a three-head system may occupy less than 10 L in some cases, particularly when using shared components. These examples are merely illustrative, however, and are not limiting on the scope of the present disclosure.

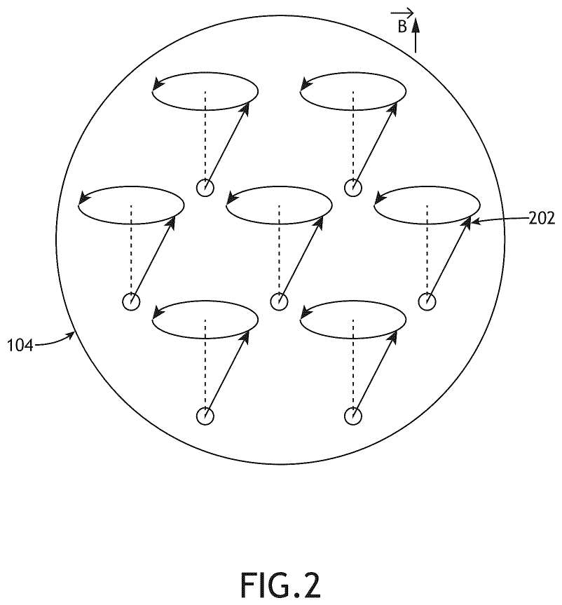

Referring now to FIGS. 2-8, various aspects of the quantum magnonic interferometer 100 and its operation are described in greater detail, in accordance with one or more embodiments of the present disclosure.

FIG. 2 illustrates a schematic view of spins 202 in a spherical ferrimagnetic resonator 104, in accordance with one or more embodiments of the present disclosure. In FIG. 2, all the spins 202 are aligned and may be tuned by an external magnetic field B. It is contemplated herein that the spins may precess in phase in response to changes in the external magnetic field, which results in a strong resonance change in response to the magnetic field changes. As a result, ferrimagnetic resonators 104 may operate as extremely sensitive magnetic field detectors within the quantum magnonic interferometer 100.

It is contemplated herein that the quantum magnonic interferometer 100 may mitigate various source of noise to provide robust and sensitive measurements.

For example, providing opposing magnetic bias fields across a pair of ferrimagnetic resonators 104 may enable the isolation of signals associated with an external magnetic field from various noise sources. As described above, this configuration provides that each spin-wave ferrimagnetic resonance may be quantized by a reference axis of opposite sign such that resonance frequencies of the pair of ferrimagnetic resonators 104 shift in opposing directions in response to an external magnetic field. However, other external quantities such as temperature changes, stress-strain changes, native fluctuations of the applied magnetic bias fields, or the like will induce common mode shifts of the resonance frequencies that do not impact a differential signal between the pair and may thus be isolated and mitigated when performing a measurement. This architecture mimics the differential and common mode shifts observed in atomic orbitals, analogous to the Zeeman and Stark effects commonly exploited in double-quantum magnetometry.

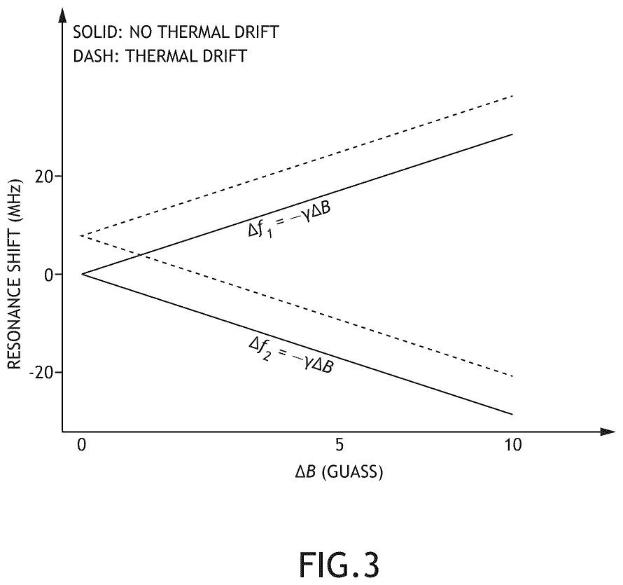

FIG. 3 illustrates common-mode noise rejection using a pair of ferrimagnetic resonators 104 in the presence of opposing applied magnetic bias fields. In particular, FIG. 3 illustrates a plot of resonance shift of ferrimagnetic resonators 104 in the presence of opposing applied magnetic bias fields and an additional external magnetic field (ΔB), in accordance with one or more embodiments of the present disclosure.

As shown in FIG. 3, an external magnetic field (ΔB) to be measured may induce an increase in the resonance frequency of one of the ferrimagnetic resonators 104 and a decrease in the resonance frequency of the other of the ferrimagnetic resonators 104. Accordingly, the magnitude of the external magnetic field may be determined through a differential measurement.

As further shown in FIG. 3, common-mode noise sources (e.g., noise sources common to both ferrimagnetic resonators 104 such as, but not limited to, thermal drift) may result in common shifts of the resonance signals, which does not impact a differential measurement. As a result, the systems and methods disclosed herein may mitigate such common-mode noise sources.

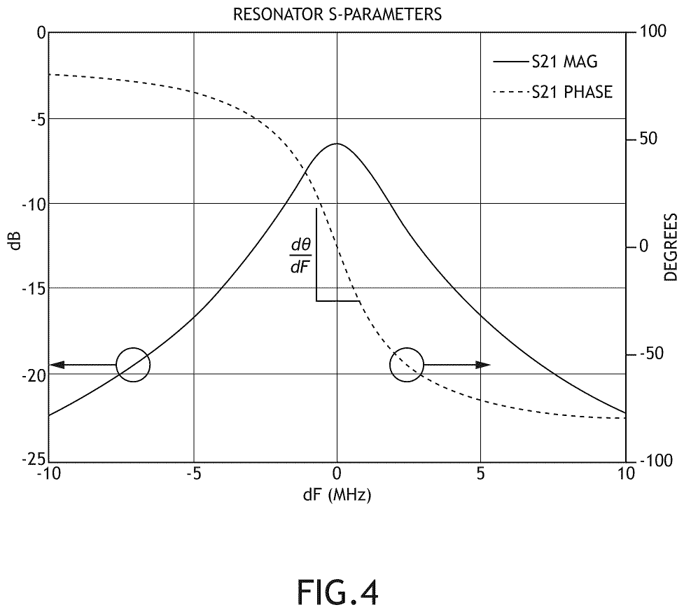

FIG. 4 illustrates a plot of magnitude and phase of a resonance of a ferrimagnetic resonator 104, in accordance with one or more embodiments of the present disclosure. For example, the resonance of a typical YIG ferrimagnetic resonator 104 with a Q of 3500 and center frequency of 5 GHz has a phase slope of 1.4 [μrad/Hz]. As the ferromagnetic resonance changes according to the electron gyromagnetic ratio (28 GHZ/T), the magnetic phase slope of a differential measurement of dual-resonator residual phase detectors 110 is

$$\frac{d θ}{d T} = 2 \times 1.4 E - 6 [ rad / Hz ] \cdot 28 E 9 [ Hz / T ] = 78 [ krad / T ] .$$

From here, the phase noise floor of the phase detectors 110 can be compared with the magnetic phase slope to determine the magnetic sensitivity. A typical phase detector 110 (e.g., a mixer phase detector) may have a noise floor of −170 [dBc/Hz] which, when taking into account the magnetic phase slope, corresponds to an effective magnetic sensitivity of 4E⁻¹⁴[T/\sqrt{Hz}]. Such analysis can then be performed over the modulation frequency range, taking into account mixer flicker noise. It is to be understood that FIG. 4 and the associated description is provided solely for illustrative purposes and should not be interpreted as limiting the scope of the present disclosure.

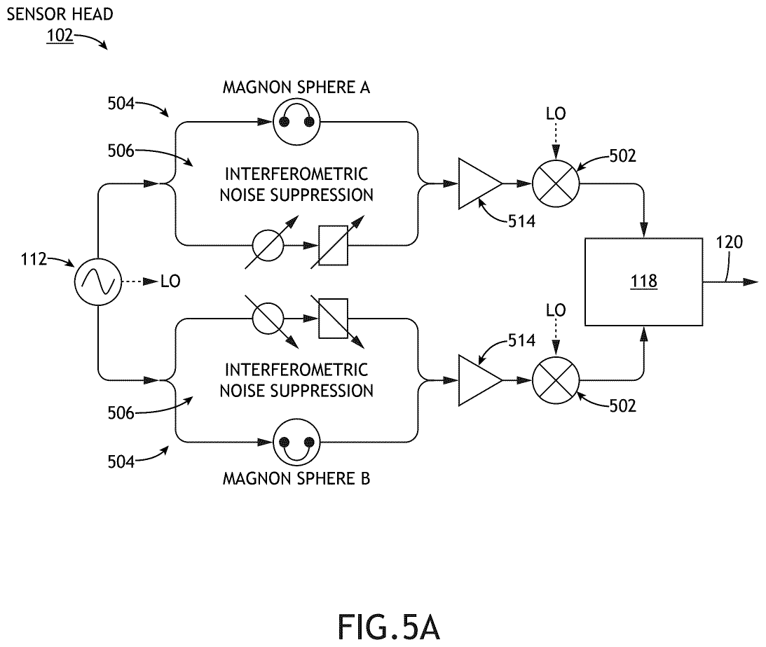

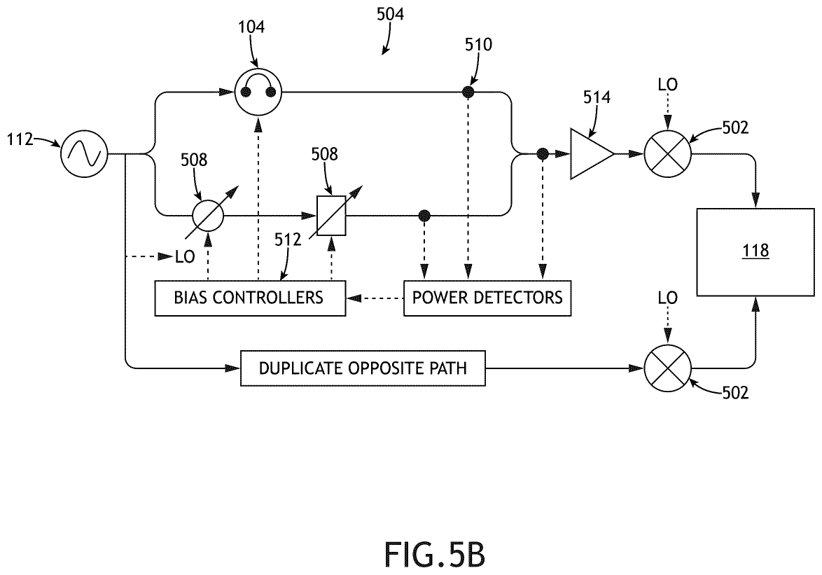

Referring now to FIGS. 5A-5B, differential phase detection is described in greater detail, in accordance with one or more embodiments of the present disclosure.

FIG. 5A illustrates a diagram of phase detectors 110 and differential detection circuitry 118 in a sensor head 102, in accordance with one or more embodiments of the present disclosure.

As shown in FIG. 5A, the carrier signal 108 may be split and coupled with each of the ferrimagnetic resonators 104 to provide that the phases of the carrier signals 108 may be modified in the presence of an external magnetic field. The phase detectors 110 may then include mixers 502 that extract a phase difference between carrier signals 108 modified by ferrimagnetic resonators 104 through mixing with a tap of an unmodified portion of the carrier signals 108 (LO in FIG. 5A). The outputs of the mixers 502 are then fed to the differential detection circuitry 118 for generation of the detection signals 120.

In some embodiments, the quantum magnonic interferometer 100 incorporates interferometric noise suppression to reduce a noise floor of the differential phase measurement of carrier signals 108 interacting with a pair of ferrimagnetic resonators 104.

FIG. 5B illustrates a diagram of an interferometric carrier suppression bridge 504 in a phase detector 110, in accordance with one or more embodiments of the present disclosure. In FIG. 5B, the interferometric carrier suppression bridge 504 includes an interferometer 506 with a ferrimagnetic resonator 104 in one arm and modulators 508 (e.g., amplitude and/or phase modulators) in the other arm. In this configuration, a carrier signal 108 may be split and passed through the interferometer. Power detectors 510 may monitor the power in each arm, which may be used by bias controllers 512 to drive the modulators 508 to maintain alignment of the interferometer 506. Accordingly, the signal to noise ratio of phase shifts induced by the ferrimagnetic resonators 104 may be improved. Interferometric noise suppression is generally described in E. Rubiola and V. Giordano, Advanced interferometric phase and amplitude noise measurements, Rev. Sci. Instrum. 73, 2445 (2002); which is incorporated by herein by reference in its entirety.

In some embodiments, the phase detectors 110 further include amplifiers 514 (e.g., low-noise amplifiers) prior to the mixers 502. In a simple residual configuration, the mixers 502 may be the dominant noise contributor to the resulting detection floor. To bypass this limitation, an amplifier 514 (e.g., a low-noise amplifier) may be added to a phase detector 110 prior to the mixer 502, which allows the effective noise figure to become that of the amplifier 514 rather than the mixer 502.

Further, when combined with an interferometric carrier suppression bridge 504, The interferometric carrier-suppression bridge 504 may address flicker noise of the amplifier 514 that would otherwise dominate at close-in offsets. Since the flicker noise of the amplifier 514 is proportional to the incident power level of the carrier signal 108, the interferometric carrier-suppression bridge 504 allows the amplifier 514 to operate at zero effective input power.

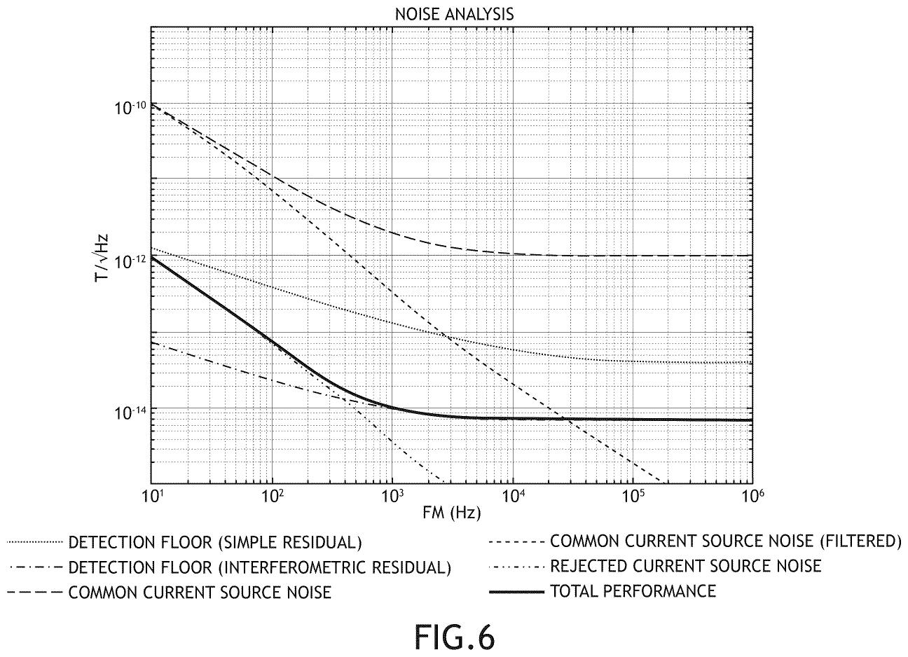

FIG. 6 illustrates a plot of sensitivity of the quantum magnonic interferometer 100 limited by different noise sources, in accordance with one or more embodiments of the present disclosure. The Detection Floor (Simple Residual) trace represents performance without interferometric noise suppression, while the Detection Floor (Interferometric Residual) represents performance incorporating interferometric noise suppression (e.g., via the interferometric carrier suppression bridges 504). The interferometric carrier suppression method serves to reduce the effective mixer contribution, providing a 10 dB improvement to the white noise floor and a significant (>20 dB) improvement to the flicker noise floor. The Common Current Source Noise trace represents a typical low-noise current source driving the bias coils. The Common Current Source Noise (Filtered) trace represents the actual current noise through the bias coil due to the coil's self-inductive filtering. The Rejected Current Source Noise trace represents the suppressed effective bias noise due to the common-mode rejection of the residual measurement. The Total Performance trace indicates the final noise floor of the quantum magnonic interferometer 100 revealing excellent noise floor performance with some slight close-in degradation caused by finite bias noise rejection. It is to be understood, however, that FIG. 6 and the associated description is provided merely for illustrative purposes and is not limiting on the scope of the present disclosure. The performance of any particular implementation may depend on the particular components used.

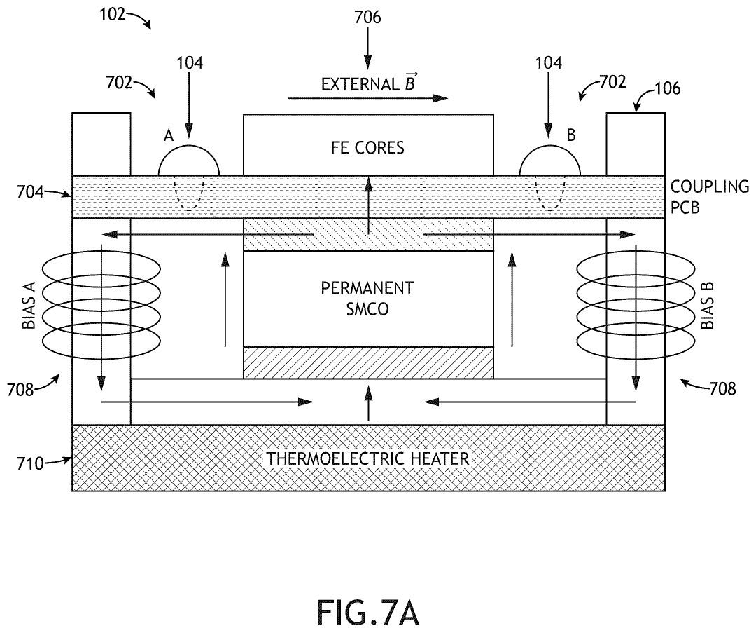

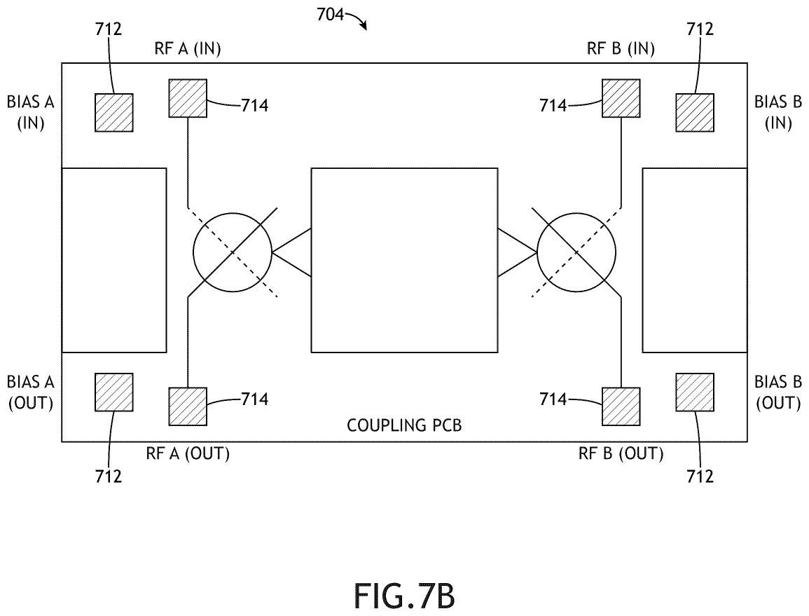

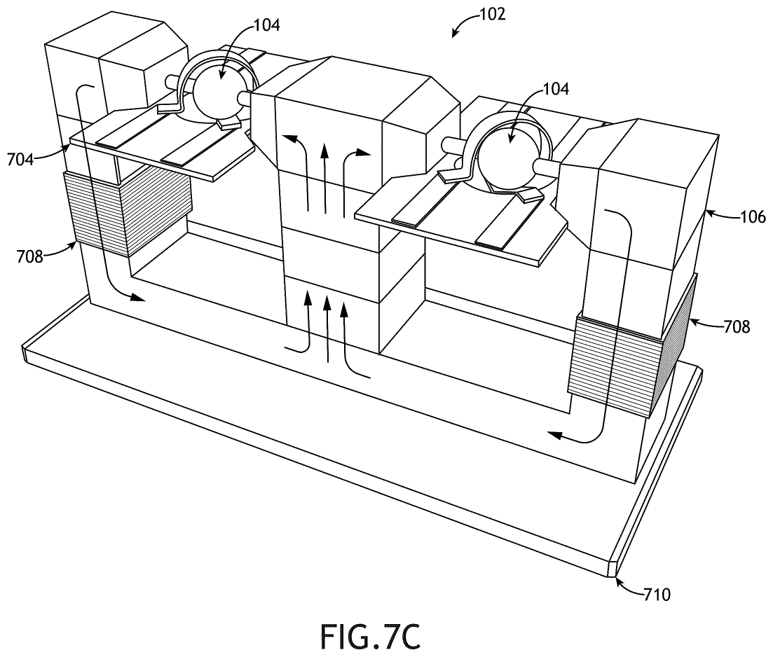

Referring now to FIGS. 7A-7C, a non-limiting example implementation of a quantum magnonic interferometer that incorporates a pair of ferrimagnetic resonators 104 in opposite regions 702 of a biased yoke magnet 106, in accordance with one or more embodiments of the present disclosure. FIG. 7A illustrates a side schematic view of a sensor head 102, in accordance with one or more embodiments of the present disclosure. FIG. 7B illustrates a top schematic view of a circuit board 704 for interfacing with the ferrimagnetic resonators 104, in accordance with one or more embodiments of the present disclosure. FIG. 7C is a perspective view of the sensor head 102 associated with FIGS. 7A and 7B, except that the circuit board 704 is shown as two components instead of a single component as in FIG. 7B, in accordance with one or more embodiments of the present disclosure.

In FIGS. 7A-7C, a permanent magnet core 706 provides the primary bias field for the ferrimagnetic resonators 104. For example, FIG. 7A depicts the permanent magnetic core 706 as including iron (Fe) cores and a permanent samarium cobalt (smco) magnet. FIGS. 7A-7C further depict tuning circuitry 114 in the form of supplementary bias coils 708 arranged on each return path for fine frequency tuning. The ferrimagnetic resonators 104 are shown as spherical resonators placed using inert pedestals on opposite sides of the yoke. Further, FIGS. 7A-7C depict a thermoelectric heater 710 operating as a temperature controller 116 to provide operation at a consistent, controlled temperature.

In FIG. 7B, the circuit board 704 provides contacts for various signals for the operation of the sensor head 102. For example, FIG. 7B depicts contacts 712 for control of the supplemental bias coils (e.g., the tuning circuitry 114). As another example, FIG. 7B depicts contacts 714 for RF signals used to probe the ferrimagnetic resonators 104 (e.g., the carrier signals 108). Further, although not explicitly shown, the circuit board 704 may include contacts for controlling the thermoelectric heater 710.

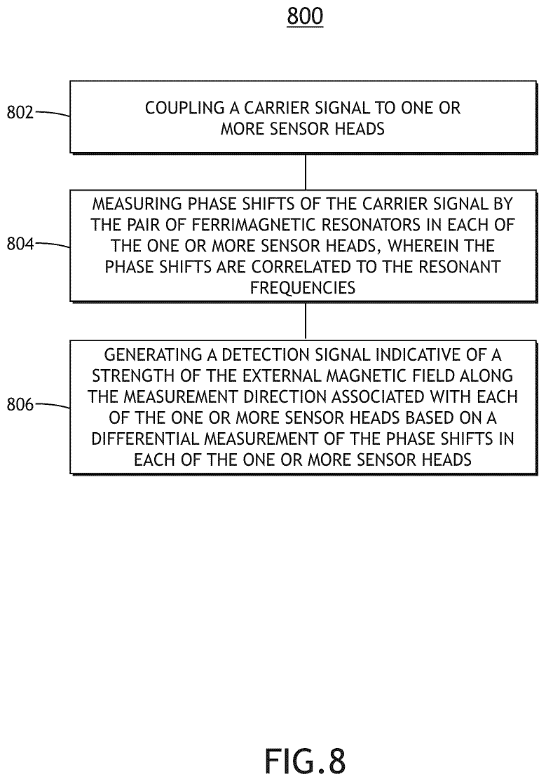

FIG. 8 is a block diagram of a magnetometry method 800, in accordance with one or more embodiments of the present disclosure. The embodiments and enabling technologies described previously herein in the context of the quantum magnonic interferometer 100 should be interpreted to extend to the method 800. For example, the processors of the controller 122 may be configured to execute program instructions stored on the memory, where the program instructions cause the processors to perform any of the steps of the method 800 either directly or indirectly (e.g., by generating control signals to direct another component to perform an action). However, the method 800 is not limited to the architecture of the quantum magnonic interferometer 100.

The method 800 may include a step 802 of coupling a carrier signal 108 to one or more sensor heads. The method 800 may include a step 804 of measuring phase shifts of the carrier signal 108 by a pair of ferrimagnetic resonators 104 in each of the one or more sensor heads 102, where resonance frequencies of the ferrimagnetic resonators 104 are sensitive to an external magnetic field, and where the phase shifts are correlated to the resonant frequencies. The method 800 may further include a step 806 of generating a detection signal indicative of a strength of the external magnetic field along the measurement direction associated with each of the one or more sensor heads based on a differential measurement of the phase shifts in each of the one or more sensor heads 102. For example, as described with respect to the quantum magnonic interferometer 100 in FIGS. 1A-7, the pair of ferrimagnetic resonators 104 in each sensor head 102 may be exposed to opposite magnetic bias fields such that the resonance frequencies (and the associated phase shifts) of the pair of ferrimagnetic resonators 104 shift in opposite directions (e.g., with opposite signs) in the presence of an external magnetic field. A detection signal may then be generated for each sensor head 102 based on a differential phase measurement of carrier signals 108 coupled to the associated pair of ferrimagnetic resonators 104.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A magnetometer comprising:
an oscillator configured to generate a carrier signal;
one or more sensor heads, each comprising:
a pair of ferrimagnetic resonators with resonant frequencies matched to the carrier signal;
one or more magnets configured to bias the pair of ferrimagnetic resonators with opposing magnetic bias fields, wherein an external magnetic field in a measurement direction aligned with the opposing magnetic bias fields modifies the resonant frequencies of the pair of ferrimagnetic resonators in opposite directions; and
a pair of phase detectors configured to measure phase shifts of the carrier signal by the pair of ferrimagnetic resonators, wherein the phase shifts are correlated to the resonant frequencies; and
differential detection circuitry configured to generate a detection signal indicative of a strength of the external magnetic field along the measurement direction associated with each of the one or more sensor heads based on a differential measurement of the phase shifts in each of the one or more sensor heads.

2. The magnetometer of claim 1, wherein the one or more magnets comprise a biased yoke magnet, wherein the pair of ferrimagnetic resonators are placed in opposite regions of the biased yoke magnet.

3. The magnetometer of claim 1, wherein the pair of phase detectors include interferometric carrier-suppression bridges to control noise in the detection signal.

4. The magnetometer of claim 1, wherein the pair of ferrimagnetic resonators comprise yttrium iron garnet (YIG) resonators.

5. The magnetometer of claim 1, further comprising tuning circuitry to match the resonant frequencies of the pair of ferrimagnetic resonators and a frequency of the carrier signal.

6. The magnetometer of claim 1, further comprising:
a thermal controller to control a temperature of at least one of the one or more sensor heads.

7. The magnetometer of claim 1, wherein the one or more sensor heads comprise three sensor heads arranged in orthogonal directions, wherein the detection signals from the three sensor heads provide a three-dimensional measurement of the external magnetic field.

8. The magnetometer of claim 1, wherein the one or more sensor heads comprise an array of sensor heads.

9. A magnetometer sensor head comprising:
a pair of ferrimagnetic resonators;
one or more magnets configured to bias the pair of ferrimagnetic resonators with opposing magnetic bias fields, wherein an external magnetic field in a measurement direction aligned with the opposing magnetic bias fields modifies resonant frequencies of the pair of ferrimagnetic resonators in opposite directions; and
a pair of phase detectors configured to measure phase shifts of a carrier signal by the pair of ferrimagnetic resonators, wherein a frequency of the carrier signal matches the resonant frequencies of the pair of ferrimagnetic resonators, wherein the phase shifts are correlated to the resonant frequencies, wherein a differential measurement of the phase shifts provides a measurement of the external magnetic field along the measurement direction.

10. The magnetometer sensor head of claim 9, wherein the one or more magnets comprise a biased yoke magnet, wherein the pair of ferrimagnetic resonators are placed in opposite regions of the biased yoke magnet.

11. The magnetometer sensor head of claim 9, wherein the pair of phase detectors include interferometric carrier-suppression bridges.

12. The magnetometer sensor head of claim 9, wherein the pair of ferrimagnetic resonators comprise yttrium iron garnet (YIG) resonators.

13. The magnetometer sensor head of claim 9, further comprising tuning circuitry to match the resonant frequencies of the pair of ferrimagnetic resonators and a frequency of the carrier signal.

14. The magnetometer sensor head of claim 9, further comprising:
a thermal controller to control a temperature of the pair of ferrimagnetic resonators.

15. A magnetometry method comprising:
coupling a carrier signal to one or more sensor heads, each comprising:
a pair of ferrimagnetic resonators with resonant frequencies matched to the carrier signal; and
one or more magnets configured to bias the pair of ferrimagnetic resonators with opposing magnetic bias fields, wherein an external magnetic field in a measurement direction aligned with the opposing magnetic bias fields modifies resonant frequencies of the pair of ferrimagnetic resonators in opposite directions;
measuring phase shifts of the carrier signal by the pair of ferrimagnetic resonators in each of the one or more sensor heads, wherein the phase shifts are correlated to the resonant frequencies; and
generating a detection signal indicative of a strength of the external magnetic field along the measurement direction associated with each of the one or more sensor heads based on a differential measurement of the phase shifts in each of the one or more sensor heads.

16. The magnetometry method of claim 15, further comprising:
tuning the resonant frequencies of the pair of ferrimagnetic resonators to match a frequency of the carrier signal.

17. The magnetometry method of claim 15, further comprising:
controlling a temperature of at least one of the one or more sensor heads.

18. The magnetometry method of claim 15, wherein the one or more magnets comprise a biased yoke magnet, wherein the pair of ferrimagnetic resonators are placed in opposite regions of the biased yoke magnet.

19. The magnetometry method of claim 15, wherein measuring the phase shifts of the carrier signal by the pair of ferrimagnetic resonators comprises measuring the phase shifts via interferometric carrier-suppression bridges to control noise in the detection signal.

20. The magnetometry method of claim 15, wherein the one or more sensor heads comprise three sensor heads arranged in orthogonal directions, wherein generating the detection signal indicative of the strength of the external magnetic field along the measurement direction based on the differential measurement of the phase shifts comprises generating detection signals indicative of the strength of the external magnetic field along the orthogonal directions.
